(19) United States
(12) Patent Application Publication
(10) Pub. No.: US 2002/0008590 A1
(43) Pub. Date: Jan. 24, 2002

(54) Quadrature HF oscillator with isolating amplifier

(76) Inventors: Johan David Van Der Tang, Eindhoven (NL); Wolfdietrich Georg Kasperkovitz, Waalre (NL)

Correspondence Address: U. S. Philips Corporation, 580 White Plains Road, Tarytown, NY, 10591, US

(21) Appl. No.: 09/886,198

(22) Filed: Jun. 21, 2001

(30) Foreign Application Priority Data
Jun. 26, 2000 (EP) 00202210.1

(51) Int. Cl. H03B 5/02

(52) U.S. Cl. 331/45; 331/57

(57) ABSTRACT

Described is a quadrature HF ring oscillator (1) comprising at least two cascaded filters (2, 3) each having a filter output (O1, O2) to be coupled to a quadrature load (Z_{I}, Z_{Q}), each of the two filters (2, 3) comprises an isolating amplifier (T5-T8) coupled between the filter output (O1, O2) and the quadrature load (Z_{I}, Z_{Q}). Advantageously the isolating amplifier forms a buffer between the oscillating core of the oscillator oscillating in the GHz range and the quadrature load, so that output frequency and amplitude are less influenced by the load.

The present invention relates to a quadrature HF ring oscillator comprising at least two cascaded filters each having a filter output to be coupled to a load.

The present invention also relates to a communication device, e.g. a satellite receiver front-end or broadcast device, a frequency-convertor, a transmission device for example an optical transmission front-end, the communication device having a quadrature HF ring oscillator comprising at least two cascaded filters each having an filter output to be coupled to a load.

Such a quadrature high frequency oscillator is known from WO 95/01671 (U.S. Pat. No. 5,949,295). The known oscillator is a completely monolitically integrated controllable ring oscillator comprising frequency dependent filter stages in the form of differential amplifiers each having active loads embodied by transistors operated in a common collector circuit. Each active load represents an inductance together with parasitic and interconnect capacitances and possibly lumped/internally added capacitances forming frequency dependent elements of the ring oscillator. In addition appropriate voltage and current sources in the filter stages are used to tune the centre frequency of the bandpass filter thus realised. Herein quadrature filter output signals are tapped from the base terminals and the collector terminals of the differential amplifier transistors respectively.

It is a disadvantage of the known high frequency oscillator that starting an oscillation and in particular maintaining the oscillation at the tuned frequency of the oscillator when loaded with an appropriate load is not possible or at least not possible sufficiently accurately, without substantially influencing the oscillator frequency.

Therefore it is an object of the present invention to provide a quadrature HF ring oscillator which is sufficiently output frequency and amplitude stabile, in particular when electrically loaded by some circuit.

Thereto the quadrature HF ring oscillator according to the invention is characterised in that at least each of the two filters comprises an isolating amplifier to be coupled to the load.

It is an advantage of the quadrature HF ring oscillator according to the invention that the isolating amplifier acts as a buffer and isolates a load of the oscillator from the oscillator core or oscillation sensitive part itself. In effect this means that both the oscillator output frequency and the quadrature output amplitude are less influenced by a loading of the oscillator. The result is that the oscillator is now capable of oscillating at a higher and less muffled frequency. In addition it is even possible to omit a lumped/intentionally added capacitance completely, so that the parasitic integrated capacitances, i.e. interconnect capacitance and device parasitics, of semiconductors usually present in the realisation of the oscillator are the only capacitances used therein. This then saves the aforementioned added capacitance in the realisation of the oscillator according to the invention. Furthermore tuning is less rigid and can be effected more effectively, accurately because tuning is now not severely effected by the loading circuits at the output of the oscillator.

An embodiment of the quadrature HF ring oscillator according to the invention has the characterising that the isolating amplifier comprises an easy to integrate semiconductor circuit.

A further embodiment of the quadrature HF ring oscillator according to the invention is characterised in that the semiconductor circuit is equipped with an inductive reactance.

It is an advantage of this embodiment that the same semiconductor that forms the isolating amplifier can at the same time be used to implement the inductive reactance. This way the semiconductor circuit performs a double function, which reduces the number of components to integrate even further.

An easy to integrate implementation of the quadrature HF ring oscillator according to the invention is characterised in that the filters comprise transconductance circuits.

A still further embodiment of the quadrature HF ring oscillator according to the invention is characterised in that the filters are equipped with common differential bipolair, CMOS and/or NMOS semiconductors.

Another more specific embodiment of the quadrature HF ring oscillator according to the present invention is characterised in that the load is a quadrature load. This is the case if both outputs are not summed so that the load then is a quadrature load.

At present the quadrature HF ring oscillator and communication device according to the invention will be elucidated further together with their additional advantages while reference is being made to the appended drawing, wherein similar components are being referred to by means of the same reference numerals. In the drawing:

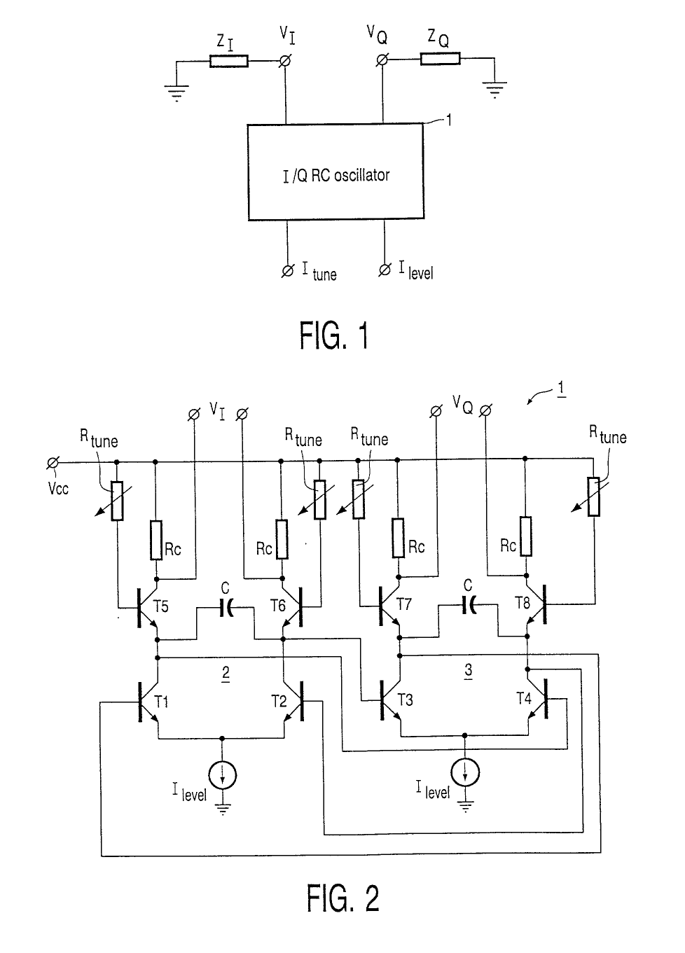

FIG. 1 shows an main architectural of a prior art quadrature HF ring oscillator;

FIG. 2 shows a first embodiment of the quadrature HF ring oscillator according to the invention;

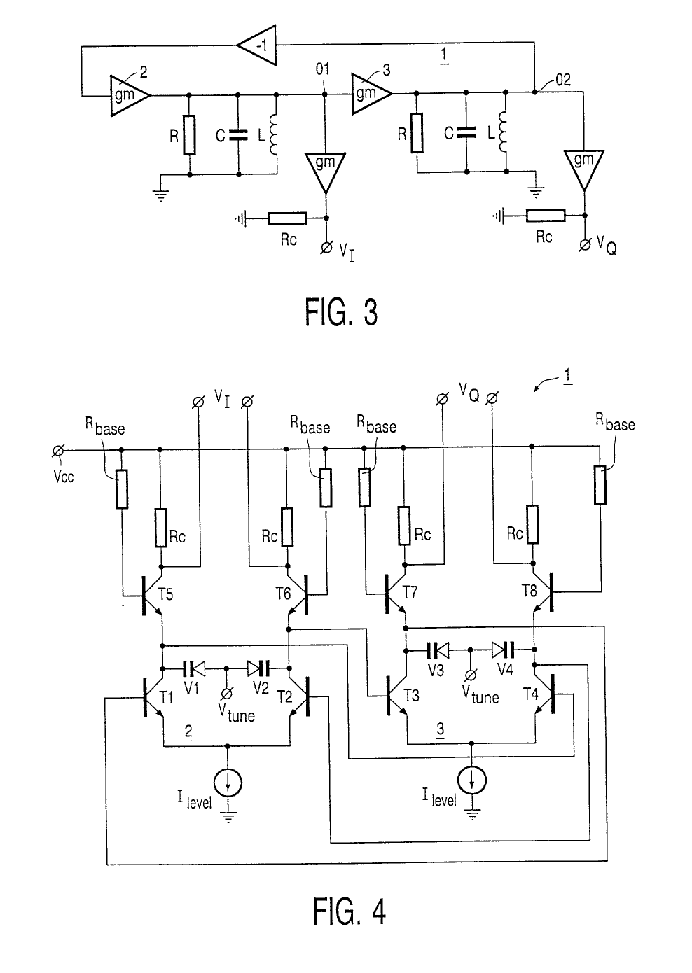

FIG. 3 shows a so called behaviour model of the oscillator of FIG. 2;

FIGS. 4-6 show second, third, and fourth respective embodiments of the quadrature HF ring oscillator according to the invention.

FIG. 1 shows a main architecture of a quadrature HF ring oscillator 1. The oscillator 1 has control inputs, in particular current control inputs Iₜᵤₙₑ and Iₗₑᵥₑₗ for controlling the frequency and amplitude respectively of quadrature oscillator output signals V_{I} and V_{Q} loaded by loads Z_{I} and Z_{Q}. If the output signals V_{I} and V_{Q} are summed the load will be a non quadrature load. In the cases to be described the loads are considered quadrature loads, which can however easily be summed to form a non quadrature load. Such an oscillator provides output signals in the GHz frequency range for application in communication devices, for example high frequency (HF) receivers such as for satellites, transmitters, transceivers, oscillators, telephones, transmission devices, such as optical interfaces in particular digital optical transmission devices, and the like for transfer to and load by for example mixers, phase detectors, dividers, front-end circuits, clock recovery circuits, frequency conversion circuits etcetera. There is a obvious tendency towards low cost and higher oscillator output frequencies generated in a limited chip area at the expense of a low power consumption both in the professional and consumer market. The loading and the coupling out of the quadrature HF oscillator output signal rises problems as to sufficiency of oscillator output amplitude, tuning and stability.

FIG. 2 shows a fully integrated quadrature HF ring oscillator 1 comprising two filters 2 and 3 in a cascade of equal quadrature differential sections. Each section comprises an earth coupled tail current source Iₗₑᵥₑₗ for the differential semiconductor pairs T1, T2 and T3, T4 respectively. The main stream path, that is the collector emitter path of each of the semiconductors T1-T4 comprise common collector (emitter follower) semiconductors T5-T8. Base impedances Rₜᵤₙₑ coupled between the bases of each semiconductor T5-T8 and the supply terminal Vcc are capable of tuning the frequency of oscillator output signals V_{I} and V_{Q} at the collectors of T5-T8. Collector impedances Rc are coupled between the collectors of T5-T8 and the supply terminal Vcc. The output is taken from the collectors of the semiconductors T5-T8. This way the semiconductors T5-T8 isolate the quadrature outputs from the sensitive oscillating main stream paths of oscillator semiconductors T1-T4. Each section 2, 3 provides a phase reversal of 90 degrees and the feedback path from the second filter section 3 to the first filter section 2 realises an inversion, so that the ring oscillator 1 as a whole provides a 360 degrees phase reversal in order to generate the GHz oscillation output signal. Any further basic functioning and calculation details of the present quadrature oscillator 1 can be found in U.S. Pat. No. 5,949,295 which is included herein by reference thereto.

FIG. 3 shows a basic a so called behaviour model of the oscillator 1 of FIG. 2. The blocks indicated gm therein are transconductances whereto the current Iₗₑᵥₑₗ is input and V_{I} and V_{Q} are output. −1 indicates a phase reversal of 180 degrees. R at filter outputs O1 and O2 represents the ohmic losses of a filter section, C represents the capacitance C of FIG. 2 which includes paracitic capacitances of the semiconductors of FIG. 2, and L represents the inductances simulated by the controllable semiconductors T5 and T6, T7 and T8. This fig. shows that the oscillator output signal V_{I} and V_{Q} derived from the filter outputs O1 and O2 are buffered and isolated from the sensitive oscillator core, wherein the GHz oscillator signal is generated. In quadrature load conditions with Rc=50 Ω, Rₜᵤₙₑ=5 kΩ, Iₗₑᵥₑₗ=4 mA, the oscillator simulated output frequency was 14.777 GHz at a simulated buffer output voltage of 115 mV peak, using a process with a 30 GHz transistor transition frequency.

FIG. 4 shows a second embodiment of the quadrature HF oscillator 1, wherein Rₜᵤₙₑ is fixed in R_{base} and output frequency voltage tuning is now realised by a antiwise connection in series of varicaps V1, V2 and V3, V4 as shown, coupled to the main stream path of semiconductors T1-T4. The quadrature outputs at V_{I} and V_{Q} are isolated from the oscillating sensitive parts of the oscillator 1 by the semiconductors T5-T8.

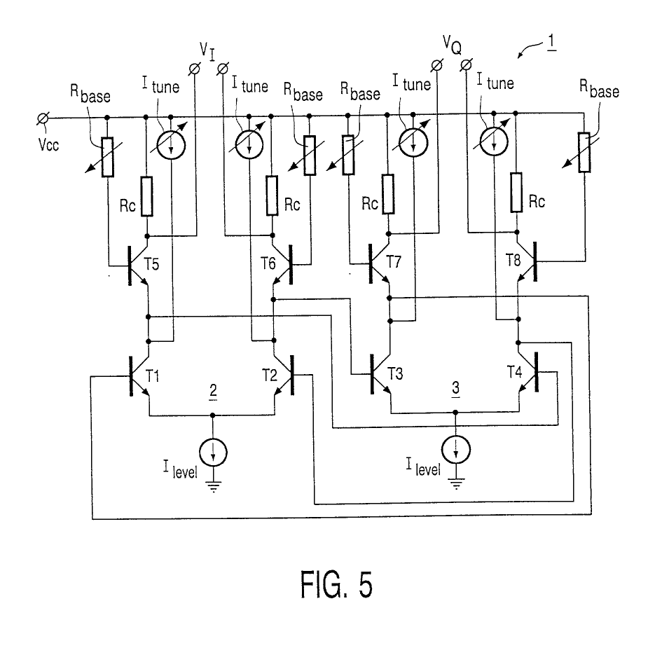

FIG. 5 shows a third embodiment of the quadrature HF oscillator 1, wherein tuning takes place by means of current sources Iₜᵤₙₑ coupled between the main stream path of semiconductors T1-T4 and power supply line Vcc. The quadrature outputs at V_{I} and V_{Q} are again isolated from the oscillating sensitive parts of the oscillator 1 by the semiconductors T5-T8.

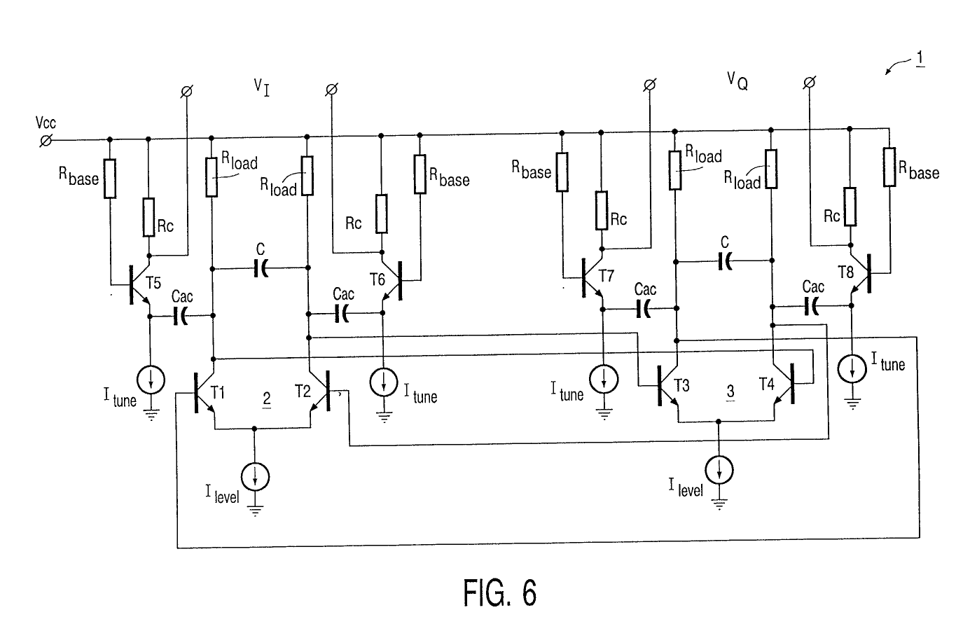

FIG. 6 shows a preferred fourth embodiment of the quadrature HF oscillator 1 in that instead of cascoding T1 and T5, T2 and T6, T3 and T7, T4 and T8, as disclosed in the aforementioned embodiments these mentioned semiconductors are no longer connected in cascode but AC coupled through integrated additional capacitors C_{ac} to the sensitive oscillator core. Because of the AC coupling this embodiment has an extended tuning range. In addition it is a low voltage arrangement saving approximately V_{be}−(Iₗₑᵥₑₗ*R_{load}/2) in Vcc voltage, but having the same above mentioned advantages. In addition this fourth embodiment enables additional tuning possibilities, because the oscillation frequency can be varied using Iₜᵤₙₑ coupled between the emitters of T5-T8 respectively and earth, apart from optionally varying R_{base} or capacitor C. This architecture has an additional coupling of Iₜᵤₙₑ to earth and is therefore less current efficient then the other above embodiments.

The semiconductors T1-T8 may be integrated differential bipolair, CMOS and/or NMOS semiconductors. In additionally possible practical embodiments of the quadrature HF ring oscillator 1 more than two cascaded filter sections 2 and 3 could at wish be applied while having some isolating amplifier as explained in the above, either in differential or in non differential form.

1. A quadrature HF ring oscillator (1) comprising at least two cascaded filters (2, 3) each having a filter output (O1, O2) to be coupled to a load (Z_{I}, Z_{Q}), characterised in that at least the two filters (2, 3) comprises an isolating amplifier (T5-T8) coupled between the filter output (O1, O2) and the load (Z_{I}, Z_{Q}).

2. The quadrature HF ring oscillator (1) according to claim 1, characterised in that the isolating amplifier comprises a semiconductor circuit (T5-T8).

3. The quadrature HF ring oscillator (1) according to claim 1 or 2, characterised in that the semiconductor circuit (T5-T8) is equipped as an inductive reactance (L).

4. The quadrature HF ring oscillator (1) according to one of the claims 1-3, characterised in that the filters (2, 3) comprise transconductance circuits (gm).

5. The quadrature HF ring oscillator (1) according to one of the claims 1-4, characterised in that the filters (2, 3) are equipped with differential bipolair, CMOS and/or NMOS semiconductors (T1-T8).

6. The quadrature HF ring oscillator (1) according to one of the claims 1-5, characterised in that the load is a quadrature load (Z_{I}, Z_{Q}).

7. A communication device, e.g. a satellite front-end receiver or broadcast device, a frequency-convertor, a transmission device for example an optical transmission front-end, the communication device having a quadrature HF ring oscillator (1) according to one of the claims 1-6, comprising at least two cascaded filters (2,3) each having a filter output (O1, O2) to be coupled to a load (Z_{I}, Z_{Q}), characterised in that each of the two filters (2, 3) comprises an isolating amplifier (T1-T4) coupled between the filter output (O1, O2) and the load (Z_{I}, Z_{Q}).
